(19) United States
(12) Patent Application Publication
(10) Pub. No.: US 2022/0146444 A1
(43) Pub. Date: May 12, 2022

(54) METHOD FOR MEASURING RESISTIVITY OF SILICON SINGLE CRYSTAL

(71) Applicant: SHIN-ETSU HANDOTAI CO., LTD., Tokyo (JP)

(72) Inventors: Fumitaka KUME, Chiyoda-ku (JP); Yukari SUZUKI, Annaka-shi (JP); Koichi KITAMURA, Echizen-shi (JP); Masahiro YOSHIDA, Nishigo-mura (JP); Shuji YOKOTA, Nishigo-mura (JP); Koji EBARA, Annaka-shi (JP)

(73) Assignee: SHIN-ETSU HANDOTAI CO., LTD., Tokyo (JP)

(21) Appl. No.: 17/435,275

(22) PCT Filed: Jan. 27, 2020
(86) PCT No.: PCT/JP2020/002800

§ 371 Date: Aug. 31, 2021

(30) Foreign Application Priority Data
Mar. 6, 2019 (JP) 2019-040643

(51) Int. Cl. G01N 27/04; G01N 1/28; G01N 1/34; G01N 1/44

(52) U.S. Cl. CPC G01N 27/041; G01N 1/286; G01N 2001/2866; G01N 1/44; G01N 1/34

(57) ABSTRACT

A method for measuring a resistivity of a silicon single crystal by a four-point probe method including: a first grinding step of grinding at a surface of the silicon single crystal on which the resistivity is measured; a cleaning step of cleaning the silicon single crystal subjected to the first grinding step; a donor-annihilation heat treatment step of heat-treating the silicon single crystal subjected to the cleaning step; and a second grinding step of grinding at least the surface of the silicon single crystal subjected to the donor-annihilation heat treatment step on which the resistivity is to be measured, where the resistivity of the silicon single crystal is measured by the four-point probe method after performing the second grinding step. This provides a method for measuring a resistivity of a silicon single crystal by which stable measurement is possible over a long period of time after a donor-annihilation heat treatment.

### TECHNICAL FIELD

The present invention relates to a method for measuring a resistivity of a silicon single crystal.

### BACKGROUND ART

Methods for measuring a resistivity of a silicon single crystal by a four-point probe method are defined in Non Patent Document 1 (SEMI MF84-0312 “Test Method for Measuring Resistivity of Silicon Wafers with an In-line Four-point Probe”) and Non Patent Document 2 (JIS H 0602 “Testing method of resistivity for silicon crystals and silicon wafers with four-point probe”).

Equipment used for the measurement by the four-point probe method is periodically calibrated by using a NIST sample described in Non Patent Document 3 (NIST Special Publication 260-131, 2006 Ed. “The Certification of 100 mm Diameter Silicon Resistivity SRMs 2541 Through 2547 Using Dual-Configuration Four-Point Probe Measurements, 2006 Edition”).

Multiple methods are proposed as methods of treatment before the measurement of a silicon single crystal resistivity by the four-point probe method.

Patent Document 1 proposes removing an oxide film on a surface of a substrate to be tested or reducing the thickness of the oxide film to be 0.5 nm or less, and then measuring the resistivity within 4 hours.

Patent Document 2 proposes, in a method for measuring the resistivity of a silicon wafer having a resistivity of 2000 Ω·cm or higher: subjecting the silicon wafer to a donor-annihilation treatment; then after at least 2 hours have elapsed, removing, by means of a water-free treatment, a surface layer on a surface of the silicon wafer to be measured by a thickness of 10 nm or more; and bringing an electrode needle into contact with the surface to be measured from which the surface layer has been removed to measure the resistivity.

The water-free treatment in Patent Document 2 is, for example, buffing. A reason for performing such a treatment is to remove an oxide film with an upper-limit film thickness of 10 nm formed on the surface of the wafer by the donor-annihilation treatment. By removing the surface layer of the wafer by a thickness of 10 nm or more, the oxide film is completely removed, so that favorable electrical contact can be achieved during measurement of the resistivity between an electrode used for measuring and the surface of the wafer to be measured.

Patent Document 3 proposes a wafer for inspection for evaluating physical properties with contact and/or evaluating physical properties without contact, where a surface of the wafer to be inspected is a high-brightness surface-ground surface.

When the evaluation of physical properties with contact disclosed in Patent Document 3 is measurement of resistivity by a four-point probe method, a donor-annihilation treatment is performed after high-brightness surface grinding.

Patent Document 4 discloses etching a sample wafer piece with an etching solution of HF:HNO₃=1:5, performing a donor-annihilation heat treatment in an atmosphere of 650° C. for 45 min or 1100° C. for 60 min, and then polishing the surface to measure resistivity.

A donor-annihilation heat treatment is a well-known art that is performed as a pre-treatment of resistivity measurement. For example, Patent Document 3 states as follows. “In measurement of resistivity, a heat treatment called donor annihilation is performed. When a silicon single crystal manufactured by a CZ method is annealed at a low temperature of around 450° C., a few oxygen atoms collect to release one electron (thermal donor). It is known that the produced amount of these thermal donors increases in proportion to the annealing time, but is annihilated when the annealing temperature becomes 600° C. or higher. If such thermal donors are present in the silicon, resistivity appears to decrease in n-type silicon, for example. On the other hand, in p-type silicon, resistivity appears to increase.”

Accordingly, in order to evaluate accurate resistivity (resistivity owing to the dopant), it is necessary to annihilate these thermal donors, and a donor-annihilation heat treatment needs to be performed. In heat treatment, if the surface of the wafer for inspection is contaminated by the adhesion of impurities, etc., a problem of the contamination of the heat treatment furnace occurs. In addition, directly placing a wafer for inspection in a heat treatment furnace after slicing leads to cracks occurring in the wafer for inspection. Therefore, etching is performed as a pre-treatment of the heat treatment.

### CITATION LIST

### Patent Literature

### Patent Document 1: JP 2002-76080 A

### Patent Document 2: JP 2015-26755 A

### Patent Document 3: JP 2001-118902 A

### Patent Document 4: JP 2018-93086 A

### Non Patent Literature

### Non Patent Document 1: SEMI MF84-0312

### Non Patent Document 2: JIS H 0602

### Non Patent Document 3: NIST Special Publication 260-131, 2006 Ed.

### SUMMARY OF INVENTION

### Technical Problem

As described above, Patent Document 1 proposes removing an oxide film on a surface of a substrate to be tested or reducing the thickness of the oxide film to be 0.5 nm or less, and then measuring the resistivity within 4 hours. According to Patent Document 1, the measured value of the resistivity is more or less stable with a time of being left of up to about 4 hours. However, with more than 4 hours, the measured value rises, and becomes unstable.

An object of Patent Document 2 is to suppress the fluctuation of resistivity immediately after a donor-annihilation treatment by removing 10 nm or more of the wafer surface after at least 2 hours have passed after the donor-annihilation treatment to remove the oxide film. This is because composites of oxygen atoms and dopant atoms become separated after the donor-annihilation treatment, and the dopant becomes reactivated. Therefore, only resistivity of up to 70 hours after the donor-annihilation treatment is disclosed in the Examples of Patent Document 2.

On the other hand, the high-brightness surface grinding described in Patent Document 3 is for adjusting the surface state of the sample, and is performed before the donor-annihilation treatment.

Patent Document 4 discloses etching a sample wafer piece sliced from an ingot block ground to a diameter dimension larger than that of an ingot block for wafer manufacturing process, performing a donor-annihilation heat treatment, and then polishing the surface to measure resistivity. However, there is no description whatever regarding what kind of surface treatment was carried out for what purpose. According to the above-described conventional arts, it can be assumed that the object is to remove the oxide film formed during the donor-annihilation treatment.

As described, the above proposals have been made regarding fluctuation in resistivity that occurs in a silicon single crystal, in particular, a high-resistivity silicon single crystal in a period of a few days from immediately after the donor-annihilation heat treatment, but there have been no proposals whatever concerning fluctuation of resistivity that occurs in a period of a week or more after the donor-annihilation heat treatment. However, a method by which resistivity can be measured stably over a long period of time is necessary in order to ensure the resistivity of a silicon single crystal, in addition, to give a value of a different silicon single crystal, and furthermore, to control a measuring instrument with which the resistivity of the silicon single crystal is measured.

The present invention has been made to solve the above-described problems, and an object thereof is to propose a method for measuring a resistivity of a silicon single crystal by which stable measurement is possible over a long period of time after a donor-annihilation heat treatment. Note that the silicon single crystal in the present invention includes not only a silicon single crystal with a wafer shape, but also silicon single crystals with a fragment shape of a ¼-wafer, etc., a strip shape, a chip shape, a block shape, and the like.

### Solution to Problem

To achieve the object, the present invention provides a method for measuring a resistivity of a silicon single crystal by a four-point probe method, the method for measuring a resistivity of a silicon single crystal comprising:

a first grinding step of grinding a surface of the silicon single crystal;

a cleaning step of cleaning the silicon single crystal subjected to the first grinding step;

a donor-annihilation heat treatment step of heat-treating the silicon single crystal subjected to the cleaning step; and

a second grinding step of grinding the surface of the silicon single crystal subjected to the donor-annihilation heat treatment step,

wherein the resistivity of the silicon single crystal is measured by the four-point probe method after performing the second grinding step.

According to such a method for measuring a resistivity of a silicon single crystal, heating and cooling in the donor-annihilation heat treatment step can be made uniform within the silicon single crystal by including a first grinding step before the donor-annihilation heat treatment step. Therefore, a stable donor-annihilation heat treatment can be performed. In addition, by performing the second grinding step after the donor-annihilation heat treatment, the contact condition between the probe tip and the surface of the silicon single crystal to be measured can be made favorable in resistivity measurement in a four-point probe method. Furthermore, stable measurement becomes possible over a long period of time since the surface of the silicon single crystal can be kept as a ground surface even after the donor-annihilation heat treatment. By thus including a first and second grinding steps before and after a donor-annihilation heat treatment step, the method for measuring a resistivity of a silicon single crystal makes it possible to measure stably over a long period after the donor-annihilation heat treatment.

In the inventive method for measuring a resistivity of a silicon single crystal,

a hydrofluoric acid treatment step of treating the silicon single crystal with hydrofluoric acid can be performed after the donor-annihilation heat treatment step, and

the second grinding step can be performed subsequently.

In the present invention, a hydrofluoric acid treatment step for removing an oxide film formed on the surface of the silicon single crystal can thus be performed after the donor-annihilation heat treatment step and before the second grinding step.

The inventive method for measuring a resistivity of a silicon single crystal can be applied particularly suitably when the resistivity of the silicon single crystal is 5000 Ω·cm or higher.

According to the inventive method for measuring a resistivity of a silicon single crystal, a value of a different silicon single crystal can be given or a resistivity measuring instrument can be controlled, with the silicon single crystal after being subjected to the second grinding step as a standard sample, and a measured value of the resistivity measured by the four-point probe method as a standard value.

When remeasuring the standard value of the standard sample, a resistivity is preferably remeasured by the four-point probe method after grinding the surface of the standard sample, and the remeasured value is preferably used as a new standard value of the standard sample.

In this manner, the silicon single crystal can be used as a standard sample over a longer period.

Furthermore, high-brightness surface grinding is preferably performed in the first grinding step and/or the second grinding step.

The silicon single crystal can be ground to an even more uniform thickness by the first high-brightness surface grinding. Therefore, the heating and the cooling in the donor-annihilation heat treatment step can also be made even more uniform, so that the donor-annihilation effect within the silicon single crystal can be made uniform. Furthermore, the surface of the silicon single crystal can be ground homogeneously by the second high-brightness surface grinding. Therefore, the influence of the surface state of the silicon single crystal can be reduced at the time of resistivity measurement.

Therefore, desirably, the high-brightness surface grinding is performed in the first grinding step and the second grinding step,

both surfaces of the silicon single crystal are ground in the high-brightness surface grinding performed in the first grinding step, and

the surface of the silicon single crystal on which the resistivity is to be measured is ground in the high-brightness surface grinding performed in the second grinding step.

According to such a method, the thickness of the silicon single crystal can be adjusted with higher precision in the first grinding step before the donor-annihilation heat treatment. In addition, in the second grinding step, at least the surface on which the resistivity of the silicon single crystal is to be measured can be adjusted to be a homogeneous surface ground with high brightness.

### Advantageous Effects of Invention

According to the inventive method for measuring a resistivity of a silicon single crystal, a stable donor-annihilation heat treatment can be performed, and at the same time, the surface of the silicon single crystal can be kept as a ground surface even after the donor-annihilation heat treatment. Therefore, stable measurement over a long period of time becomes possible. In particular, the resistivity of a high-resistivity silicon single crystal can be ensured over a long period. In addition, the method makes it possible to measure stably, over a long period, a resistivity of a sample used for giving values of other silicon single crystals and for controlling a measuring instrument for measuring high resistivity.

### BRIEF DESCRIPTION OF DRAWINGS

FIG. 1 is a schematic flow diagram showing an example of the inventive method for measuring resistivity.

FIG. 2 is a graph showing the daily fluctuation of resistivity in Comparative Examples 1, 2, and 3.

FIG. 3 is a graph showing the daily fluctuation of resistivity in Example 1.

### DESCRIPTION OF EMBODIMENTS

Hereinafter, embodiments of the present invention will be described on the basis of the figures.

The present invention is a method for measuring a resistivity of a silicon single crystal by a four-point probe method, the method for measuring a resistivity of a silicon single crystal comprising:

a first grinding step of grinding a surface of the silicon single crystal;

a cleaning step of cleaning the silicon single crystal subjected to the first grinding step;

a donor-annihilation heat treatment step of heat-treating the silicon single crystal subjected to the cleaning step; and

a second grinding step of grinding the surface of the silicon single crystal subjected to the donor-annihilation heat treatment step,

wherein the resistivity of the silicon single crystal is measured by the four-point probe method after performing the second grinding step.

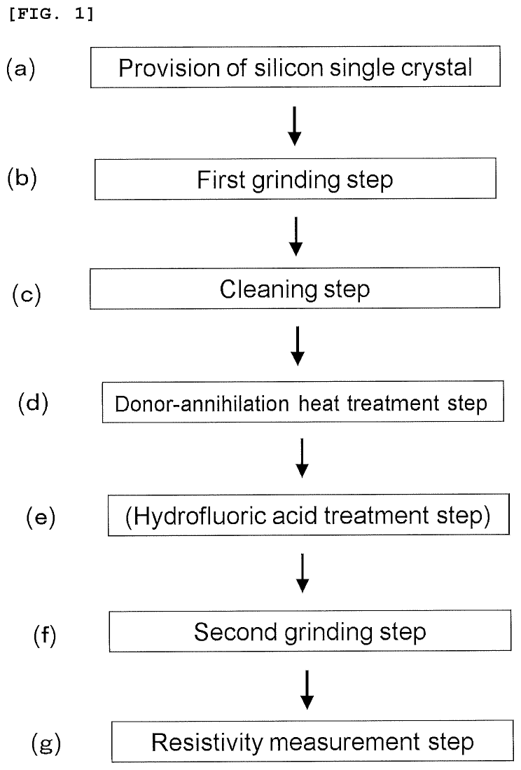

FIG. 1 is a schematic flow diagram showing an example of the inventive method for measuring resistivity. Firstly, a silicon single crystal is provided (FIG. 1(a) provision of silicon single crystal). Here, a wafer in a thin plate form can be sliced from any part of an ingot pulled by a CZ method (Czochralski method) as a silicon single crystal used for measuring resistivity.

Next, at least the surface of the silicon single crystal provided in FIG. 1(a) on which the resistivity is to be measured is ground (FIG. 1(b) first grinding step). For example, the surface of the sliced silicon single crystal can be ground with a size #240 to #2000 to obtain a ground surface. In particular, when high-brightness surface grinding is performed in the first grinding step (first high-brightness surface grinding step), both surfaces (main front surface and back surface) of a silicon single crystal are first coarsely ground using a coarse grindstone of about #325 to adjust the thickness, then further ground using a grindstone of #1500 or higher, and finally subjected to high-brightness surface grinding of about 50 μm in both sides together to achieve a desired glossiness. In the case of mirror-polishing, the single-side polishing stock removal is about 10 μm.

Note that high-brightness surface grinding indicates grinding of a silicon single crystal so as to obtain a high-brightness surface having glossiness of 70% or higher when glossiness of the silicon single crystal made into a mirror-polished wafer is set as 100%. The glossiness of the ground surface formed by high-brightness surface grinding is more preferably 90% or higher, and particularly preferably 98% or higher when the glossiness of a mirror-polished wafer is set as 100%. Incidentally, glossiness can be measured by a method for measuring specular glossiness in which glossiness is evaluated at an incidence angle of 60 degrees to a sample surface.

By performing the first grinding step before the donor-annihilation heat treatment step, heating and cooling in the donor-annihilation heat treatment step can be made uniform within the silicon single crystal. In particular, when a high-brightness surface grinding is performed in the first grinding step, the thickness of the silicon single crystal can be adjusted with higher precision compared with etching or lapping. Therefore, the heating and cooling in the donor-annihilation heat treatment step becomes more uniform within the silicon single crystal and the annihilation level of thermal donors also becomes uniform, so that the resistivity of the silicon single crystal can be measured more accurately.

Subsequently, the silicon single crystal subjected to the first grinding step is cleaned (FIG. 1(c) cleaning step). For example, the silicon single crystal can be cleaned using ammonia (NH₃) water with hydrogen peroxide (H₂O₂) water, hydrofluoric acid (HF) water with hydrogen peroxide (H₂O₂) water, and the like. This cleaning step prevents the heat treatment furnace to be used in the subsequent step of donor-annihilation heat treatment from being contaminated.

Subsequently, the donor-annihilation heat treatment step of heat-treating the silicon single crystal subjected to the cleaning step is performed (FIG. 1(d)). In this donor-annihilation heat treatment step, the silicon single crystal is heat-treated, for example, by using a horizontal furnace, a vertical furnace, or an RTP furnace in a nitrogen gas atmosphere at 650° C. or 1100° C. to annihilate oxygen donors.

An oxide film is formed on the surface of the silicon single crystal in the donor-annihilation heat treatment step, and accordingly, the oxide film can be removed using an aqueous hydrofluoric acid (HF) solution (FIG. 1(e) hydrofluoric acid treatment step). However, this step may be omitted since the oxide film can be removed in the next second grinding step. The oxide film can be removed with certainty by treating with an aqueous hydrofluoric acid (HF) solution.

The surface of the silicon single crystal becomes altered in the donor-annihilation heat treatment step or the hydrofluoric acid treatment step. An insulator film (oxide film or nitride film) is formed in the donor-annihilation heat treatment, and the dopant becomes inactivated due to hydrogen ions in the hydrofluoric acid treatment. Accordingly, at least the surface of the silicon single crystal subjected to the donor-annihilation heat treatment step on which the resistivity is to be measured is ground (FIG. 1(f) second grinding step). This second grinding step (FIG. 1(f)) is performed to shave off several μm to several tens of μm of the altered surface of the silicon single crystal, at the same time, returning to a ground surface.

When a high-brightness surface grinding is performed in the second grinding step (second high-brightness surface grinding step), the main front surface (the surface on which resistivity is to be measured), being the object of resistivity measurement, of the silicon single crystal is coarsely ground using a coarse grindstone of about #325 to adjust the thickness of the silicon single crystal. Then, the main front surface is further ground using a grindstone of #1500 or higher, and finally subjected to high-brightness surface grinding of 20 to 30 μm on one side to achieve a desired glossiness in the main front surface of the silicon single crystal. Grinding of the back surface (the surface on the other side of the main front surface) of the silicon single crystal has no influence on the resistivity measurement, and is therefore unnecessary but may be performed. Here, the surface roughness of a high-brightness surface grinding surface is about 400 nm, while the surface roughness of a mirror-polished surface is about 0.1 nm. Therefore, it is easy for the surface to be measured to contact a probe tip since there is appropriate unevenness, and the surface is suitable as a surface for measuring resistivity by a four-point probe method.

The thickness of the silicon single crystal can be adjusted to be more uniform when the second grinding step is high-brightness surface grinding. Therefore, the thickness can be corrected accurately when resistivity is measured by the four-point probe method.

In the present invention, high-brightness surface grinding is preferably performed in the first grinding step and the second grinding step as described above. In this event, it is preferable to grind both surfaces of the silicon single crystal in the high-brightness surface grinding performed in the first grinding step, and in the high-brightness surface grinding performed in the second grinding step, grind the surface of the silicon single crystal on which the resistivity is to be measured.

When a silicon single crystal whose main front surface is a ground surface is measured by the four-point probe method (FIG. 1(g) resistivity measurement step), the contact condition between the probe tip and the silicon single crystal is favorable, and therefore, daily fluctuation in resistivity can be almost eliminated. In particular, there is almost no daily fluctuation in resistivity even when the silicon single crystal has a resistivity of 5000 Ω·cm or higher, and this is suitable for ensuring resistivity of a silicon single crystal or controlling a resistivity measuring instrument. Furthermore, a value of a resistivity of a different silicon single crystal can be given, with the silicon single crystal subjected to the method up to the second grinding step as a standard sample, and a measured value of the resistivity measured by the four-point probe method as a standard value, and using the standard value of the standard sample.

As the control of the resistivity measuring instrument, there is daily control, which is carried out every day, and calibration that is carried out every half year or every year, for example, and in either control method, the same silicon single crystal is repeatedly measured as a standard sample. When the measured value deviates from a control width given to the standard sample in daily control or calibration, the resistivity measuring instrument is judged as abnormal. Therefore, the silicon single crystal of the present invention, which has almost no daily fluctuation in resistivity, is suitably used.

However, when the same point on the same silicon single crystal is repeatedly measured as a standard sample, variation in measurement and daily fluctuation come to be gradually revealed due to the formation of a natural oxide film on the surface of the silicon single crystal or damage on the measured point caused by the probe, and so forth. In such a case, the surface of the silicon single crystal can be ground again. As a grinding means, high-brightness surface grinding can be employed, for example. That is, when giving a value of the standard value of the standard sample again, resistivity can be remeasured by the four-point probe method after grinding the surface of the standard sample, and the remeasured value can be used as a new standard value of the standard sample.

When high-brightness surface grinding is performed, the silicon single crystal becomes thin, and therefore, it is necessary to remeasure the sample thickness and resistivity, and give a standard value again. The standard value newly given in this manner returns close to the value given before the variation in measurement or daily fluctuation was revealed.

### EXAMPLE

Hereinafter, the present invention will be described more specifically with reference to an Example and Comparative Examples. However, the present invention is not limited to the Example.

### Comparative Example 1

Both surfaces of an as-cut wafer (silicon single crystal, hereinafter, “sample”) sliced from a P-type silicon single crystal ingot with a diameter of 200 mm and a crystal axis orientation of <100> pulled by a CZ method was coarsely ground with #325, and then ground with high brightness with #1700 to adjust the sample thickness to 1200 μm.

After degreasing the sample prepared in the manner described above with ethanol, the sample was further cleaned using ammonia (NH₃) water with hydrogen peroxide (H₂O₂) water and hydrofluoric acid (HF) water with hydrogen peroxide (H₂O₂) water to clean the sample surface.

Next, the sample was heated under a nitrogen atmosphere at 650° C. for 20 minutes to perform a donor-annihilation heat treatment. Furthermore, the sample was immersed in a 5% aqueous hydrofluoric acid solution for 2 minutes to remove an oxide film. Resistivity was measured immediately afterwards by a four-point probe method, and the resistivity was 6,000 ∜·cm.

Daily fluctuation was measured over the following 16 days, and FIG. 2 shows the results. The resistivity rose to 24 times as high in 16 days, and became 146,702 Ω·cm.

### Comparative Example 2

A P-type sample prepared by the same method as Comparative Example 1 was subjected to a donor-annihilation heat treatment, and treated with a 5% aqueous hydrofluoric acid solution. Immediately afterwards, resistivity was measured by the four-point probe method, and the resistivity was 5,000 Ω·cm.

Daily fluctuation was measured over the following 16 days, and FIG. 2 shows the results. The resistivity rose to 13 times as high in 16 days, and became 66,732 Ω·cm.

### Comparative Example 3

A P-type sample prepared by the same method as Comparative Example 1 and Comparative Example 2 was subjected to a donor-annihilation heat treatment, and treated with a 5% aqueous hydrofluoric acid solution. Immediately afterwards, resistivity was measured by the four-point probe method, and the resistivity was 10 Ω·cm.

Daily fluctuation was measured over the following 16 days, and FIG. 2 shows the results. The resistivity after 16 days was 8 Ω·cm, and was reduced to 0.8 times as high in 16 days.

### Example 1

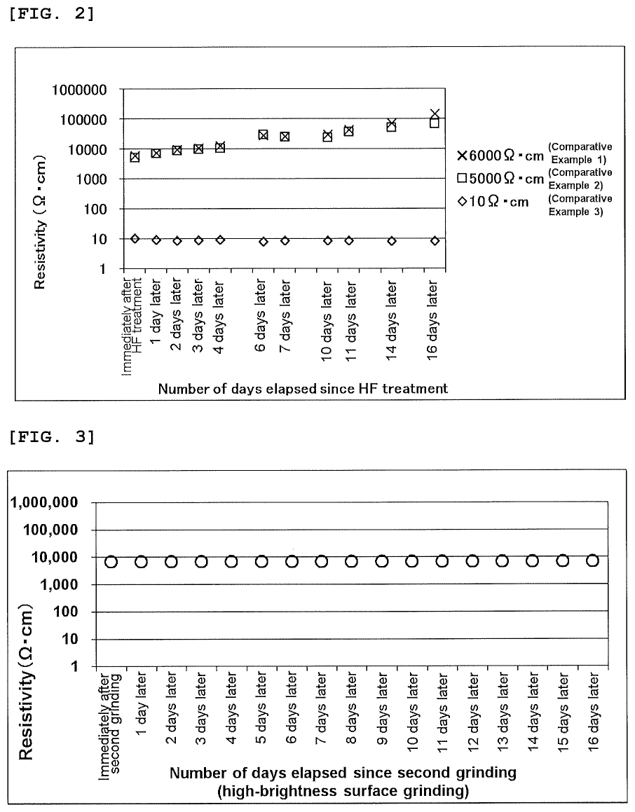

A P-type sample prepared by the same method as Comparative Examples 1 to 3 was subjected to a donor-annihilation heat treatment, and treated with a 5% aqueous hydrofluoric acid solution. Subsequently, both surfaces of the silicon single crystal were coarsely ground with #325, and then surface-ground with high brightness with #1700. Resistivity was measured immediately after the high-brightness surface grinding by the four-point probe method, and the resistivity was 6,889 Ω·cm. Daily fluctuation was measured over 16 days after the high-brightness surface grinding, and FIG. 3 shows the results. The resistivity after 16 days was 6,876 Ω·cm, and the fluctuation in the 16 days was 0.2%.

### INDUSTRIAL APPLICABILITY

According to the inventive method for measuring resistivity, heating and cooling in a donor-annihilation heat treatment step can be made uniform within a silicon single crystal. At the same time, whether after the donor-annihilation heat treatment or after a hydrofluoric acid treatment, an altered surface of the silicon single crystal can be removed by grinding, and the surface can also be kept as a ground surface. Thus, resistivity measurement that is stable over a long period of time becomes possible.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1-7. (canceled)

8. A method for measuring a resistivity of a silicon single crystal by a four-point probe method, the method for measuring a resistivity of a silicon single crystal comprising:
a first grinding step of grinding a surface of the silicon single crystal;
a cleaning step of cleaning the silicon single crystal subjected to the first grinding step;
a donor-annihilation heat treatment step of heat-treating the silicon single crystal subjected to the cleaning step; and
a second grinding step of grinding the surface of the silicon single crystal subjected to the donor-annihilation heat treatment step,
wherein the resistivity of the silicon single crystal is measured by the four-point probe method after performing the second grinding step.

9. The method for measuring a resistivity of a silicon single crystal according to claim 8, wherein
a hydrofluoric acid treatment step of treating the silicon single crystal with hydrofluoric acid is performed after the donor-annihilation heat treatment step, and
the second grinding step is performed subsequently.

10. The method for measuring a resistivity of a silicon single crystal according to claim 8, wherein the resistivity of the silicon single crystal is 5000 Ω·cm or higher.

11. The method for measuring a resistivity of a silicon single crystal according to claim 9, wherein the resistivity of the silicon single crystal is 5000 Ω·cm or higher.

12. The method for measuring a resistivity of a silicon single crystal according to claim 8, wherein a value of a resistivity of a different silicon single crystal is given or a resistivity measuring instrument is controlled, with the silicon single crystal subjected to the second grinding step as a standard sample, and a measured value of the resistivity measured by the four-point probe method as a standard value.

13. The method for measuring a resistivity of a silicon single crystal according to claim 9, wherein a value of a resistivity of a different silicon single crystal is given or a resistivity measuring instrument is controlled, with the silicon single crystal subjected to the second grinding step as a standard sample, and a measured value of the resistivity measured by the four-point probe method as a standard value.

14. The method for measuring a resistivity of a silicon single crystal according to claim 10, wherein a value of a resistivity of a different silicon single crystal is given or a resistivity measuring instrument is controlled, with the silicon single crystal subjected to the second grinding step as a standard sample, and a measured value of the resistivity measured by the four-point probe method as a standard value.

15. The method for measuring a resistivity of a silicon single crystal according to claim 11, wherein a value of a resistivity of a different silicon single crystal is given or a resistivity measuring instrument is controlled, with the silicon single crystal subjected to the second grinding step as a standard sample, and a measured value of the resistivity measured by the four-point probe method as a standard value.

16. The method for measuring a resistivity of a silicon single crystal according to claim 12, wherein when remeasuring the standard value of the standard sample, a resistivity is remeasured by the four-point probe method after grinding the surface of the standard sample, and the remeasured value is used as a new standard value of the standard sample.

17. The method for measuring a resistivity of a silicon single crystal according to claim 13, wherein when remeasuring the standard value of the standard sample, a resistivity is remeasured by the four-point probe method after grinding the surface of the standard sample, and the remeasured value is used as a new standard value of the standard sample.

18. The method for measuring a resistivity of a silicon single crystal according to claim 14, wherein when remeasuring the standard value of the standard sample, a resistivity is remeasured by the four-point probe method after grinding the surface of the standard sample, and the remeasured value is used as a new standard value of the standard sample.

19. The method for measuring a resistivity of a silicon single crystal according to claim 15, wherein when remeasuring the standard value of the standard sample, a resistivity is remeasured by the four-point probe method after grinding the surface of the standard sample, and the remeasured value is used as a new standard value of the standard sample.

20. The method for measuring a resistivity of a silicon single crystal according to claim 8, wherein high-brightness surface grinding is performed in the first grinding step and/or the second grinding step.

21. The method for measuring a resistivity of a silicon single crystal according to claim 9, wherein high-brightness surface grinding is performed in the first grinding step and/or the second grinding step.

22. The method for measuring a resistivity of a silicon single crystal according to claim 10, wherein high-brightness surface grinding is performed in the first grinding step and/or the second grinding step.

23. The method for measuring a resistivity of a silicon single crystal according to claim 11, wherein high-brightness surface grinding is performed in the first grinding step and/or the second grinding step.

24. The method for measuring a resistivity of a silicon single crystal according to claim 20, wherein
the high-brightness surface grinding is performed in the first grinding step and the second grinding step,
both surfaces of the silicon single crystal are ground in the high-brightness surface grinding performed in the first grinding step, and
the surface of the silicon single crystal on which the resistivity is to be measured is ground in the high-brightness surface grinding performed in the second grinding step.

25. The method for measuring a resistivity of a silicon single crystal according to claim 21, wherein
the high-brightness surface grinding is performed in the first grinding step and the second grinding step,
both surfaces of the silicon single crystal are ground in the high-brightness surface grinding performed in the first grinding step, and
the surface of the silicon single crystal on which the resistivity is to be measured is ground in the high-brightness surface grinding performed in the second grinding step.

26. The method for measuring a resistivity of a silicon single crystal according to claim 22, wherein
the high-brightness surface grinding is performed in the first grinding step and the second grinding step,
both surfaces of the silicon single crystal are ground in the high-brightness surface grinding performed in the first grinding step, and
the surface of the silicon single crystal on which the resistivity is to be measured is ground in the high-brightness surface grinding performed in the second grinding step.

27. The method for measuring a resistivity of a silicon single crystal according to claim 23, wherein
the high-brightness surface grinding is performed in the first grinding step and the second grinding step,
both surfaces of the silicon single crystal are ground in the high-brightness surface grinding performed in the first grinding step, and
the surface of the silicon single crystal on which the resistivity is to be measured is ground in the high-brightness surface grinding performed in the second grinding step.
